(19) United States
(12) Patent Application Publication
(10) Pub. No.: US 2019/0393371 A1
(43) Pub. Date: Dec. 26, 2019

(54) HOT-MELT LAMINATED SOLAR CLADDING STRIP

(71) Applicant: Jakob Ursing, Lund (SE)

(72) Inventor: Jakob Ursing, Lund (SE)

(21) Appl. No.: 16/016,974

(22) Filed: Jun. 25, 2018

(51) Int. Cl. H01L 31/048; B32B 7/12; B32B 37/12; B32B 37/10; B32B 17/06; B32B 3/14; B32B 38/00; H01L 31/0465; H01L 31/18

(52) U.S. Cl. CPC H01L 31/0481; B32B 7/12; B32B 37/1207; B32B 37/1018; B32B 17/06; B32B 2457/12; B32B 38/0004; H01L 31/0465; H01L 31/18; B32B 2037/1223; B32B 3/14

(57) ABSTRACT

A hot-melt laminated solar cladding strip (1) comprising a substrate (2) of a flexible membrane, a first layer of an adhesive encapsulant (3), a single electric circuit (4) comprising solar cells (5) which positive and negative sides are interconnected with wires to a single inlet (9) and a single outlet (10), a second layer of an adhesive encapsulant (11), a single or more sheets of a transparent plastic foil (12) covering and protecting the entire circuit (4) from moisture, a third layer of an adhesive encapsulant (13) and a plurality of rigid transparent tiles (14) characterized by that the tiles (14) are positioned over one or more cells (5) forming rigid groups spaced from each other with flexible gaps (15, 15′) that are positioned over tab wires (6) and/or ribbons (8) that run between said cells in said circuit allowing the strip (1) to be bent, folded or rolled.

Present invention relates to a hot-melt laminated photovoltaic strip used for cladding, comprising a substrate of a flexible membrane, a single electric circuit of solar cells encapsulated in a first and a second layer of an encapsulant adhesive, a transparent plastic foil covering the entire circuit, a third layer of an encapsulant adhesive and a plurality of rigid transparent tiles characterized by that said tiles are positioned over one or more cells forming rigid groups spaced from each other with flexible gaps that are positioned over wires that run between the cells.

### BACKGROUND OF THE INVENTION

Building Integrated Photo Voltaics (BIPV) is an interesting field for construction professionals such as architects and engineers based on a sound and sustainable idea to use the vast areas of residential buildings with many millions of roof square meters for small solar power plants. In many BIPV installations on pitched roofs the building material, in which the panel or the frameless laminate is integrated, has the sole function of a decorative support whereas the membrane laid under the BIPVs carries out the actual water protection of the building part.

In recent years however, a subgroup of BIPVs has been proposed integrating solar cells in water protecting membranes. Several arguments have been made for this, for example such systems are saving time by eliminating the need of panel supporting structures. Another argument is the gain of installing several interconnected circuits at one time needing fewer junction boxes. Yet another argument is the possibility of installing the membrane directly onto the roof providing the primary waterproofing layer of the roof.

With regards to the manufacturing there are basically two distinctive encapsulation methods depending on whether the facing is a rigid glass sheet or a flexible transparent plastic sheet. According to the understanding of the terms “rigid” versus “flexible” in present application; no rigid transparent sheet, regardless of quality and dimension, can ever be bent, rolled or folded. Glass faced solar laminates normally use single-step hot-melt vacuum lamination involving various layers of ethylene vinyl acetates (EVA) encapsulant, whereas plastic sheet faced solar laminates normally involves multiple-step roll-to-roll lamination with glass-fiber reinforced epoxy or silicone encapsulants. Furthermore, for some solar laminates a final encapsulation step involves adhesion of glass on top of the solar laminate and/or adhesion of the solar laminate on top of a separate roofing membrane or a metal sheet.

U.S. Pat. No. 4,860,509 and WO2004/066324 contemplate two-step manufacturing where pre-laminated flexible modules with transparent plastic facing sheets are mounted onto roofing membranes wherein the membranes serve as the primary waterproofing layer for the roof. US2016/0254404 specifically involves an epoxy encapsulant reinforced with glass-fiber scrims. The use of a relatively soft flexible plastic facing present a problem. The facing may for example be insufficient in protecting the laminate from scratches or staining during its operational life. Furthermore, it may present problems in protecting the circuit of solar cells from the damaging impact of hail. Finally, the glass-fiber reinforcing preventing crystalline cells from cracking presents the problem of limited bending, rolling or folding for efficient packing and shipment. Some of these concerns have been addressed in U.S. Pat. No. 5,482,569 where glass tiles are fixed on site to the laminate with silicone after the membrane has been installed to the roof. Unfortunately, this multiple-step lamination approach rockets the overall cost of the installation. JP3239635 describes a laminate solar cell roofing system comprising a flexible roofing material and glass as protective outer covering laminated by a roll-to-roll method. Flexible gaps over the laminated circuit, resulting in a strip that can be bent, folded or rolled, are not mentioned.

In patent US2008245405 Garvison et. al. proposes a waterproofing system where the facing is a rigid glass sheet. A laminate is contemplated where a substrate strip of roofing membrane has a first layer of bonding material laid on the substrate onto which a group/circuit of pre-wired photovoltaic cells are positioned. A second layer of bonding material is applied and individual rigid sheets of glass are laid on the second bonding layer, one sheet over each circuit of photovoltaic cells. Some manufacturers propose additional moisture protection to above-mentioned substrate, for example OC3's system Solarion, starting with an extra layer of bonding material onto which an opaque white plastic foil is positioned.

The patent's use of one circuit with one inlet and one output for every single rigid transparent sheet, present a problem when sheets are as small as a roof tile i.e. the area of one or a few cells. The system will prove costly, especially when the pattern of glass sheets is having the scale of a tiled roof characterized by relatively short distance between gaps, by offset gaps and sometimes by narrow gap widths. Solving this problem by simply cutting the glass sheet into smaller tiles covering a few cells, but otherwise keeping the layering of the assembly, would leave unprotected gaps over some tab wires (called positive and negative lead) in the middle of a circuit (called group) and would certainly not solve the problem of protecting the circuit from humidity posed by e.g. the wet leakage current test in the international standard IEC 61215:2005. Neither would the covering of these gaps with a narrow strip of protective tedlar/polyester between the glass tiles as suggested, since humidity and leaking electricity may travel through the thin layer of encapsulant along the sides of the narrow strip.

Accordingly, a need exists for an elongated strip of a flexible material with a single circuit of interconnected crystalline cells connected to a single electrical inlet and output in one end of the strip; and that the strip at the same time is having a facing layer of rigid transparent tiles in the scale of a pitched tiled roof spaced from each other to provide sufficient gaps to allow the finished strip to be bent, rolled or folded; and that such system should be laminated in one single step.

### SUMMARY OF THE INVENTION

Present invention contemplates novel material configurations and methods of manufacturing and installation of membrane-integrated systems that remedy some of the disadvantages of prior art. Present invention may however also be used in other product areas such as cladding of facades, vehicle-integrated photovoltaics, solar power plant structures and paving/road construction systems.

Basically, the device central to the present invention is comprised of a strip of pre-wired solar circuits on a substrate of a flexible material, such as a strip of a waterproof roofing material, that may be cut from a continuous roll before or after the cell circuit is formed thereon.

In one embodiment, a first film of encapsulating adhesive material is laid down on the substrate and pre-wired strings of preferably crystalline cells are laid down on said film and connected to a single in- and outlet forming a single electric circuit.

A second encapsulant adhesive film is placed over the circuit and a transparent plastic foil is uncoiled from a continuous roll and laid down onto said second encapsulant covering the entire circuit.

Then one or more sheets of a third encapsulant adhesive film is placed over said transparent foil and individual rigid transparent sheets are then positioned over said encapsulant to cover one or more photovoltaic cells. Preferably said sheets have the scale of a tiled roof characterized by relatively short distance between gaps, by varying gap widths and by offset gaps. Hereon forth “rigid transparent sheets” are called “tiles”.

In one embodiment, the layering onto the substrate will start with an extra layer of encapsulant film on which a plastic foil is positioned.

The assembled components are then treated in one lamination step by applying vacuum, heat and pressure thereto to remove air from the assembly, then melt and cure the encapsulant adhesives and finally press the assembly to a laminate thereby bonding the circuit to the substrate, the transparent foil to the circuit and the rigid transparent tiles to said foil. A number of patents have been identified as close prior art in patent databases concerning either solutions with rigid pieces or flexible solutions. No mixing of the two main concepts has been identified. WO 208/157803 by SOLAR INTEGRATED TECHNOLOGIES, concerns a PV panel including a plurality of rigid PV modules attached side-by-side. However, only a passage in the abstract concerns rigid PV modules, thus teaching away from rigid transparent tiles as of the claims of the present invention. The patent EP 2277693 by RENOLIT concerns foldability of PV modules. The document I split between either solution with rigid pieces or flexible solutions. No combination of the two is devised. Patent EP 1938964 by DU PONT, concerns PV panels without mentioning rolling them as roofing materials. Patent WO2014189391 by ZINNIATEK, show figures of roofing panels without mentioning hot-melt adhesives.

Accordingly, present invention proposes a novel configuration effectively providing electrical insulation of the circuit of cells under the gaps between the tiles positioned on top of said circuit during shipment, installation and operation.

The advantages of present invention are many. Firstly a multitude of gaps with various widths on top of the circuit allow for even very long e.g. 5 meter single circuits to be bent, rolled or folded for efficient shipping, handling and installation. Secondly a very long solar strip connected to a single electrical in- and outlet and thus avoiding multiple junction boxes in the middle of the strip can save amounts of time in fabrication and installation. Thirdly, the relatively small area of the tiles in combination with an additional cushioning resulting from an extra layer of encapsulant enhances the systems impact resistance providing for thinner, lighter and less costly tiles, especially for tiles made of glass. Additional advantages will be recognized from the following descriptions.

### BRIEF DESCRIPTION OF THE DRAWINGS

FIGS. 1-4 show cross-sections and layouts of the invention. Orientation, scale and proportions are solely selected for presentation reasons. In the following the invention is explained more in detail with reference to the drawing, in which

FIG. 1 shows a cross-sectional view of the strip, taken along line 1-1 where layers are separated for the sake of clarity,

FIG. 2 shows a top view, partly broken, a hot-melt laminated solar cladding strip,

FIG. 3 shows a cross-sectional view of the strip, taken along line 3-3 where players are separated for the sake of clarity,

FIG. 4 shows the principles of the sixth aspect installed on a building part,

FIG. 5 shows the principles of installing strips with angle cut ends, and

FIG. 6 shows a pitched roof and the principles of concealing a junction box.

### DETAILED DESCRIPTION OF THE INVENTION

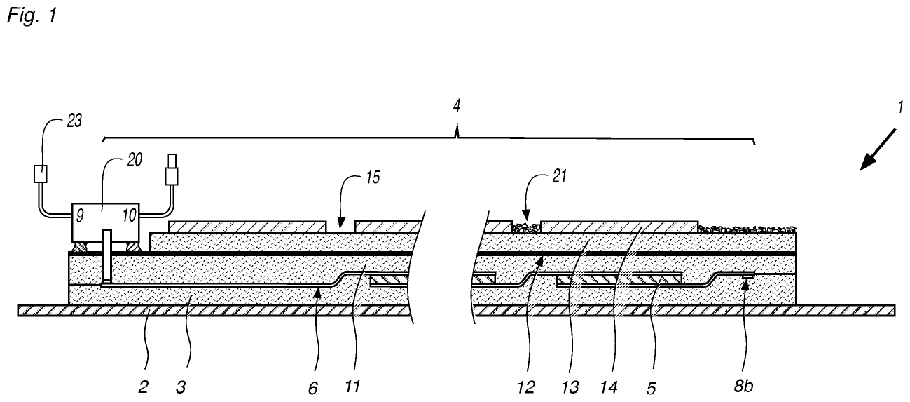

Referring now to FIG. 1 illustrating an embodiment of the invention where the substrate (2) is a roofing membrane comprising synthetic and bituminous (tar/asphalt) products. While current invention uses hot-melt adhesives as encapsulant most bituminous membranes would unfortunately not fit these adhesives' temperatures and curing times. Nevertheless, any sheet of material used to cover a flat or low-pitched roof, usually known as a membrane may be considered.

In a preferred embodiment, a substrate being a waterproof roofing material is uncoiled such as a membrane made of single or multi-ply polyvinyl chloride (PVC), ethylene vinyl acetate (EVA), thermoplastic polyolefin (TPO), filled polyolefin (FPO) or Ethylene Propylene Diene Monomer (EPDM) often in combination with plasticisers such as phthalates or EVA, and with additives such as UV- and flame retardant and with or without a reinforcing material. The most common thickness is 1.5 mm but both thicker and thinner waterproofing membranes may be used. A nonwoven fleece may also cover the backside of the substrate. In another embodiment, the assembly will start with additional layers such as glass sheets, metal profiles or thermal collectors and an extra layer of adhesive on to which the substrate is laid.

A first film of encapsulating adhesive material (3) is uncoiled and laid down on the substrate. The film may be cut from a continuous roll before or after the cell circuit is formed thereon. The term “encapsulant” means a hot-melt bonding foil providing cushioning and structural support to solar cells and circuitry, while maximizing transmission of sunlight. Encapsulant bonding is suitable for both flexible and rigid areas with excellent adhesion to all photovoltaic components. The preferred encapsulant in present invention is ethylene-vinyl acetate (EVA) having outstanding adhering and weathering properties that protects the cladding material throughout its lifecycle of approximately 25 years. The EVA base is normally combined with a number of additives in the foil extrusion process, including curing agents, UV stabilizers, antioxidants, and primers for glass adhesion. EVA's melting point when it turns to a gel is typically about 70° C. and the curing temperature and time is typically 145° C. in 15-25 min. Other encapsulant bonding materials may also be used such as thermoplastic polyurethane (TPU) or polyvinyl butyral (PVB). In one embodiment, the layering onto the substrate will start with an extra layer of encapsulant film (not shown) on which an opaque plastic foil (not shown) is positioned.

Conventional crystalline silicon solar cells (c-Si) are preferred having electrical contacts made from busbars and fingers printed on the wafer, but back contact cells, bifacial cells or thin-film cells may also be considered. The cells (5) are preferably placed in an equipment called a stringer performing the operation of “stringing” meaning interconnection of c-Si cells in series by soldering a coated copper wire, called a tab-wire (6) on the single or multiple bus bars of the c-Si cell (5). This delicate operation weaving a tab-wire (6) from electrical contacts on the front on one cell to the back on an adjacent cell and thereby bridging the gap between cells creates the string of electrical series of cells having tab-wires (6) with a fixed or alternating length.

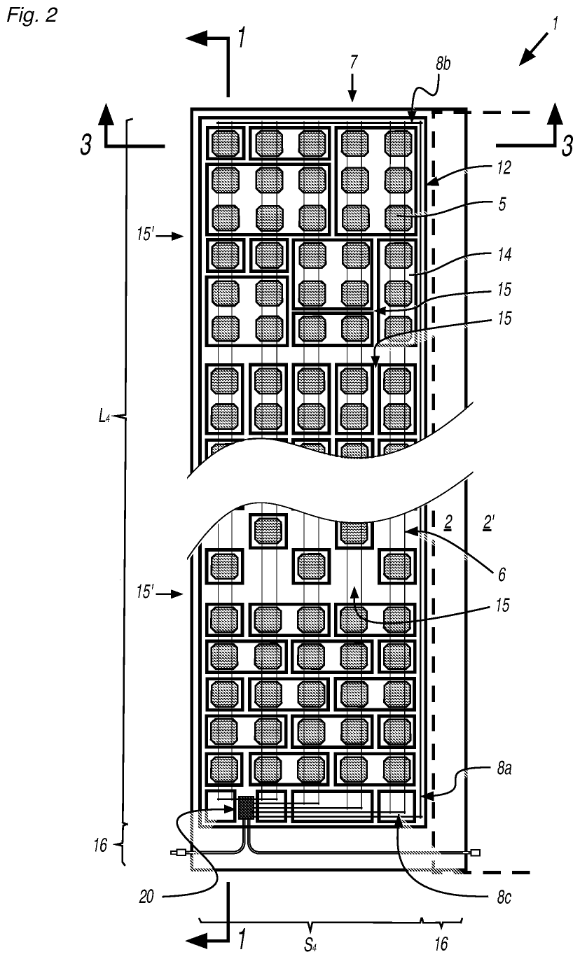

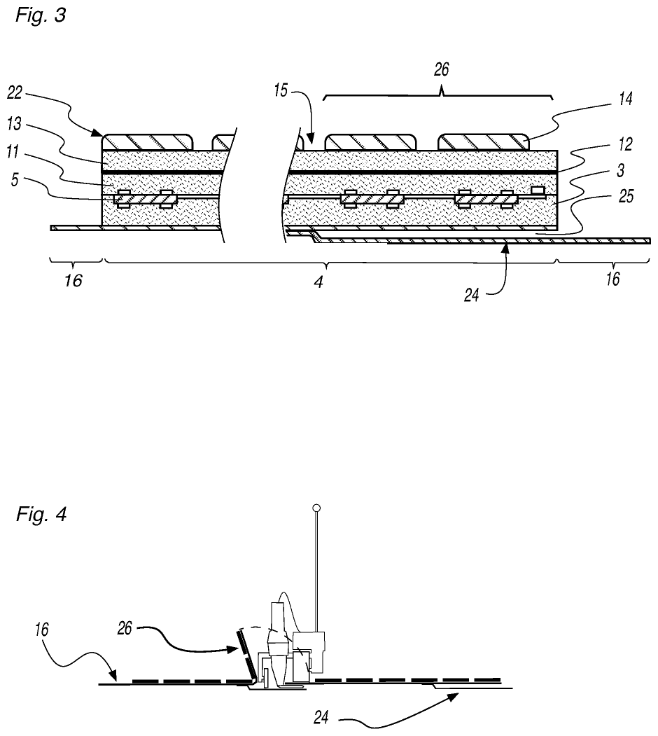

In FIG. 2, the arrows 1-1 and 3-3 refer to the cross-sectional view of FIGS. 1 and 3. Furthermore FIG. 2 is showing how one or more pre-wired strings (7) of crystalline cells (5) are laid down on said first encapsulant film (not shown). Ribbons (8a, 8b) are also laid out and connected by soldering to a single in- and outlet forming a single electric circuit (4) where the long sides (L₄) are at least one and a half times longer than the short sides (S₄).

Referring again to FIG. 1, a second encapsulant film (11) is uncoiled, potentially cut, and placed over the circuit.

Then, a transparent plastic foil (12) is uncoiled from a continuous roll and laid down onto said second encapsulant covering the entire circuit. Several polymeric products for solar laminates are currently on the market. In a preferred embodiment the transparent protecting foil is at least partially made of a transparent fluopolymer with good resistance to vapour permeation such as ethylene tetrafluoroethylene (ETFE) which is a fluorine-based plastic, but the foil may also be of other transparent plastics such as polyethylene terephthalate (PET), fluorinated ethylene propylene (FEP), perfluoroethers (PFA) or polymide (PI). Frontsheet foils come in different thicknesses most commonly 50-500 μm but thicker or thinner may also be used. DuPont Melinex and Tefzel, Saint-Gobain ETFE-E2, 3M Ultra Barrier, Krempel Akasol and AGC Fluon® films are examples of such product brands. These products are designed for high resistance and strength over a wide range of temperatures. Especially ETFE has also shown its architectural value as a building material in several large constructions such as sport stadium roofs. One or both surfaces may be treated with coating, etching or so-called corona treatment for enhanced adhesion properties.

Then, one or more sheets of a third encapsulant adhesive film (13) are placed over said transparent foil. For practical reasons current invention, a coherent layer of encapsulant on both sides of a transparent protective foil is preferred, but alternatively a multitude of cut sheets of the third encapsulant film (13) may be laid out leaving the gaps (15) without encapsulant material. Preferably however, a single sheet is uncoiled and laid out to cover the entire area of the transparent plastic foil (12), potentially with the exception of the area under the junction box (20) resulting in exposed encapsulant on the bottom of each gap (15). This provides some advantages, firstly a cost effective lay out operation and secondly the possibility of adhering granule materials (21) to the gap in the laminating process, thirdly, a positive side effect with sprinkling a granule over the gaps is that it also prevents encapsulant to stick to the upper membrane or release foil/fabric/mesh in the laminator. Material such as crushed stone, (shale or slate) or brick are common on roofs and facades and have a distinct decorative quality. Additionally, gaps between juxtaposed tiles may also be filled with a water setting or a one- or a two-component grout or sealant after installation.

Individual tiles (14) are then positioned over said encapsulant to cover one or more photovoltaic cells. Bearing in mind that the largest Tier 1 panel manufacturers report an annual output above 3 GW corresponding to more than 50 km² of 3.2 mm tempered low-iron glass per day, the possibility of thinner or thicker glass may have a considerable impact on overall costs. Current invention's tile thickness is preferably 3.2 mm tempered glass, but the technically potential thickness of a tile may be both thicker or thinner as a result of load and impact performance requirements in the standard IEC 61215:2005.

Preferably the tiles (14) have the scale of a tiled roof characterized by relatively short distance between gaps (15), by varying gap widths and by offset gaps. If tiles are made of glass they may be patterned or microstructured permitting easy lamination as well as coated, textured or etched, for non-blinding effects. Standard or low-iron glass (FeO<5%) may be used resulting in different insolation. Colored, painted, tinted, iridescent tiles may also be used creating decorative effects. Tiles may be perforated with drilled holes (not shown). Optionally tiles may be non-flat having one or more bent edges (not shown). When it comes to tile sizes most pitched roof tiles have sides measuring between 20 and 40 cm. Tile sizes should take into consideration the measurements of common rigid c-Si cells. These cells made of multi-crystalline and mono-crystalline silicon are normally measuring 5″ or 6″ (125 or 156 mm) in square but may be cut in smaller rectangles or squares.

Again, referring to FIGS. 2 and 3, the flexible gaps (15) are lined up in one or more transverse rows of gaps (15′) the width of the rows (15′) in combination with the radius (22) of the tile's edge and the thickness of the tile, have practical implications on the flexibility of the row of gaps (15′) Larger gap width or edge radius will ease the bending and even admit rolling or folding which may be practical in transporting and handling the strip (1) on the construction site. Consequently, different gap width requirements may be conceived in order to allow for the flexible gap to fulfill different options of functionality. For example, but not exclusively, a gap width that allows the cladding material in itself to become rolled into a coil and/or to become, preferably using a gap width of 5-30 mm, or folded into a fan-fold or sawtooth shaped configuration, preferably using a gap width of 30-150 mm. Glass tiles' radius (22) may be polished or created through baking of raw cut tiles. The tiles may be placed in a mold with the joint width distance, and netted on the top surface with a removable net in sheets of for example 4×5 tiles and packed in boxes and on pallets ready to be laid up for lamination.

The assembly of uncoiled materials is then cut. The term “cutting” means all kinds of operations separating pieces of material including the operations of chopping and slitting with some kind of cutting tool including a knife, saw, water-jet cutter, laser cutter, air-jet cutter, plasma cutter, guillotine cutter etc.

In order to create an electrical circuit (4), the process proceeds with the soldering of the plated tab wires to the terminal ribbons (8c) and the transverse ribbons (8b) that potentially are soldered to one or more alongside ribbons (8a). A ribbon (8a, 8b, 8c) is a plated copper wire of larger thickness than the tab wire (6) that is used for interconnecting the strings. In many photovoltaic production lines, the soldering and out-bringing of terminal ribbons (8c) ending in the junction box (20) through a cut in the substrate (2) or the transparent protecting foil (12), is performed manually. The multitude of flexible gaps (15) on top of the circuit allow for a very long e.g. 5 meter single circuits to be bent, rolled or folded for efficient shipping, handling and installation. The advantage of a very long single circuit laminated into a strip (1) is that the installers can save substantial amounts of time and money connecting each strip (1) with a single inlet and output (20).

Vacuum laminating of the assembly is preferably performed with a double-chamber laminator using belt-fed loading of the lower vacuum chamber on top of a very long heated metal plate, typically up to 6 meters. But membrane-less laminators, multiple parallel laminators, stack laminators, multi-stage laminators or continuous double belt press laminators may also be used. The laminator's cover comprises an upper vacuum chamber that opens vertically for loading and unloading modules. The lamination process involves pumping the air out of the layers in a vacuum chamber, heating the layers to melt the encapsulant, and pressing the layers together preferably with a flexible diaphragm to embed the cells in encapsulant and adhere the layers of the assembly. A flexible diaphragm is attached to the bottom of the upper vacuum chamber, and a set of valves allows the chamber above the diaphragm to be evacuated during the initial pump step and backfilled with room air during the press step. A pin lift mechanism is sometimes used to lift the laminate above the heated metal plate during the initial pump step. Active cooling systems are optional on some laminators because laminates exit the laminator at elevated temperatures, about 145° C., and need to cool down to about 45° C. typically outside on the laminator's output conveyors.

After lamination, the strip (1) is trimmed and finished including application of a junction box (20) and potentially an optimizer box. The process is done by attaching the box with a suitable silicone or glue on to the front of the transparent protecting foil (12) or on to back of substrate and by making the electrical connection terminal ribbons (8c) in the junction box (20) and the cables (23). At the inside of the box by-pass diodes may be installed connected with a string in parallel protecting the solar membrane when operating. But flat diodes may also be installed in the laminate connected in parallel with a single c-Si cell. Bypass diodes are installed to prevent cell overheating and allowing the PV modules to produce power even when partially shaded or soiled. Since diodes produce heat they are normally installed in a junction box. Normally the energy loss in diodes tends to result in designs with as many c-Si cells per diode as possible within the standard (e.g. 25 diodes). Finally, at the end of the assembly the PV module is being controlled, tested and classified where the electrical output is labelled according to the chosen classification. The tiled solar membrane is thus obtained and ready to be commercialized and installed on the field.

Optionally the strip the outside of the back material may be coated with a primer or with an adhesive coating layer and release foil to be activated by means of pressure, heat or in contact with air, humidity or a primer. There are many self-adhered bonding materials on the market based on Acrylic resin, Ethylene Vinyl Acetates (EVA), Ethylene Propylene, modified Bitumen, Natural rubber, Butyl rubber or Silicone rubber. One category is Pressure Sensitive Adhesives (PSA) usually based on an elastomer compounded with a suitable tackifier. Normally roofing membranes are adhered, screwed or otherwise secured to the roof (e.g. plywood, a roofing underlay or an existing roof) but fixing by means of ballast or vacuum may also be used. Decorative profiles may also be adhered or welded to the membrane for an aesthetically pleasing appearance.

Referring to FIG. 3, the area of the laminated substrate layer (2) is divided into a circuit area (4) and one or more protruding margins (16). The membrane may also have flashings (24) fixed to the back of the membrane creating pockets (25). Sealing a seam of two overlapping layers of membrane is normally made by means of hot air welding where the overlapping surfaces are melted where after the top layer is pressed onto the lower with a wheel. Companies such as Leister are specialized in hot-air welding technology such as automatic welders and hot-air hand tools.

Referring to FIG. 4, showing how a strip edge (26) is folded up and away from the seam making space for the hook-shaped mouthpiece of an automatic hot-air welder to reach the overlapping lips of flashing (24) and margin (16) welding them in lines giving the building part a coherent, even and decorative surface when strip edge (26) is folded back and secured.

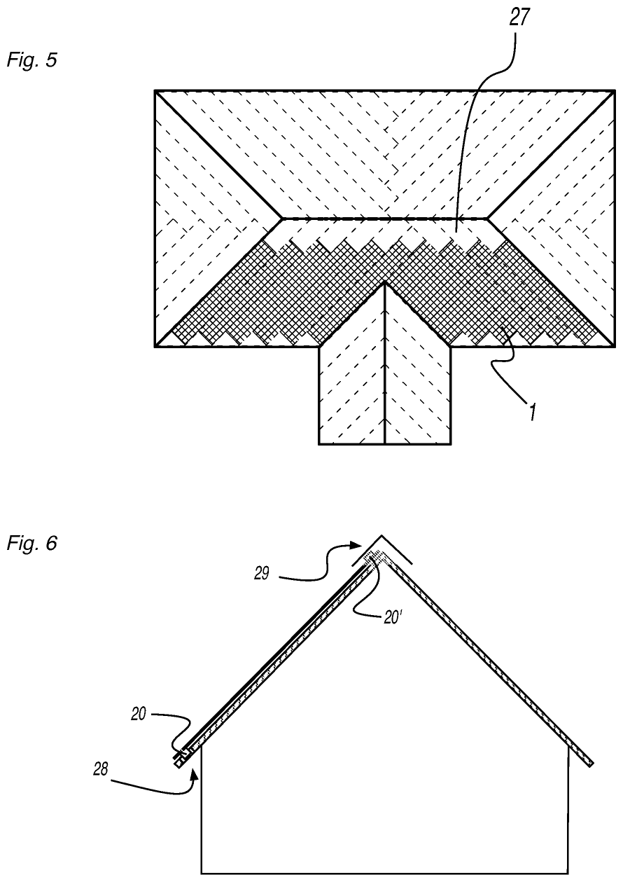

Referring to FIG. 5, showing the plan of a roof with an array of membrane strips. Some strips being integrated solar cladding strips (1) and others being a combination of membrane strips complemented with ordinary laid tiling. The strips (1) have one or two angle cut ends (27) hereby allowing for square diamond oriented tiles. The solar strip may be adhered, screwed, nailed, stapled, clamped or otherwise secured to the roof (e.g. sheathing, roofing underlay, sarking, insulation, roof battens etc. or to an existing roof). But fixing by means of ballast, vacuum or hook and loop fasteners may also be used. Profiles, decorative details and fittings may also be fixed, adhered or welded to the strip for functional or decorative purposes.

Referring to FIG. 6, showing a cross-section of a pitched roof with an integrated solar cladding strip (1). A single strip of the invention can only produce a limited amount of power. Therefore most installations will contain multiple strips, interconnection wiring, a solar inverter and sometimes a battery in a complete solar system. Electrical connections are made in series to achieve a desired output voltage and may use designated weatherproof connectors to the invention's junction box (20). As integrated solar cladding strips are designed as long as possible a junction box (20) in the middle of the roof is avoided. Preferably the junction box (20) is fixed to end of the cladding material strip where it is easy to interconnect and conceal. If concealed behind a soffit (28) it's preferably attached to the back of the strip and recessed in the underlay sheeting of the eave. If hidden under ridge flashing cap (29) it's preferably attached to the front of the strip.

In a first aspect according to the present invention it is provided a hot-melt laminated solar cladding strip wherein the hot-melt adhesive encapsulants are substantially made of ethylene vinyl acetates (EVA) or thermoplastic polyurethane (TPU) or polyvinyl butyral (PVB) with excellent adhering, cushioning properties and a transparent protecting foil substantially made of ethylene tetrafluoroethylene (ETFE) or polyethylene terephthalate (PET) or Polyvinyl chloride (PVC) with excellent weathering properties hereby protecting the electric circuit throughout its lifecycle of approximately 25 years.

In a second aspect, according to the present invention it is provided a hot-melt laminated solar cladding strip with a single circuit area formed as a long rectangle potentially with ribbons running alongside the strip returning one or more stings to a single junction box hereby avoiding multiple junction boxes in the middle of the strip.

In a third aspect of present tiled solar membrane it is formed as a strip with transverse rows of gaps giving it flexibility to be rolled into a coil or folded into a fan-fold hereby allowing for effective transport to and handling on the construction site.

In a forth aspect of present invention it is provided a substrate that is backed in the vacuum lamination with additional layers such as glass sheets, metal profiles or thermal collectors hereby improving the mechanical protection of the cell.

In a fifth aspect, the substrate is transparent hereby allowing for bifacial cells.

In a sixth aspect, according to the present invention it is provided a strip having protruding margins or fixed flashings and that the flashings have pockets allowing strips to be folded up giving room for an automatic hot-air welder to reach the overlapping lips welding the seam in lines giving the building part a waterproof and decorative surface.

In a seventh aspect, it is provided a strip having non-flat tile with one or more bent edges hereby allowing it to be installed side-by-side with non-flat roof tiles.

In an eighth aspect, it is provided a strip having a thermal collector attached to the back of the substrate after lamination hereby allowing it to be installed as a hybrid PV/T system (PVT).

In a tenth aspect, it is provided a substrate being a commercial roofing membrane, hereby using standard certifications, tools and installation procedures.

1. A hot-melt laminated solar cladding strip (1) comprising:
a substrate (2) of a flexible membrane,
a first layer of an adhesive encapsulant (3),
a single electric circuit (4) comprising solar cells (5) which positive and negative sides are interconnected with wires to a single inlet (9) and a single outlet (10),
a second layer of an adhesive encapsulant (11),
a single or more sheets of a transparent plastic foil (12) covering and protecting the entire circuit (4) from moisture,
a third layer of an adhesive encapsulant (13) and
a plurality of rigid transparent tiles (14) characterized by that the tiles (14) are positioned over one or more cells (5) forming rigid groups spaced from each other with flexible gaps (15, 15′) that are positioned over tab wires (6) and/or ribbons (8) that run between said cells in said circuit allowing the strip (1) to be bent, folded or rolled.

2. A hot-melt laminated solar cladding strip (1) according to claim 1, wherein the rigid transparent tiles (14) are made of glass.

3. A hot-melt laminated solar cladding strip (1) according to claim 1-2, wherein the first (3), second (11) and third (13) layer of hot-melt adhesive encapsulants are substantially made of ethylene vinyl acetates (EVA) or thermoplastic polyurethane (TPU) or polyvinyl butyral (PVB).

4. A hot-melt laminated solar cladding strip (1) according to claim 1-3, wherein the transparent protecting foil (12) is having a thickness of 0.05-0.5 mm and is substantially made of ethylene tetrafluoroethylene (ETFE) or polyethylene terephthalate (PET) or Polyvinyl chloride (PVC).

5. A hot-melt laminated solar cladding strip (1) according to claim 1-4, wherein the circuit (4) area is formed as a rectangle where the long sides (L₄) are at least one and a half times longer than the short sides (S₄).

6. A hot-melt laminated solar cladding strip (1) according to claim 1-4, wherein the flexible gaps (15) are lined up in one or more transverse rows (15′) having a sufficient width to allow the strip (1) to be rolled or folded.

7. A hot-melt laminated solar cladding strip (1) according to claim 1-4, wherein substrate (2) is transparent.

8. A hot-melt laminated solar cladding strip (1) according to claim 1-4, wherein the substrate (2) is at least partially backed with additional layers such as glass sheets, metal profiles or thermal collectors.

9. A hot-melt laminated solar cladding strip (1) according to claim 1-4, wherein the facing layer in the gaps (15,15′) is sand, granules or a tape.

10. An assembly operation manufacturing a hot-melt laminated solar cladding strip (1) according to claim 1 at least including the steps of;
lay-out of the substrate (2),
uncoiling a first layer of an adhesive encapsulant film (3),
stringing and lay-out of one or more strings of cells (5),
lay-out and welding of ribbons,
uncoiling a second layer of an adhesive encapsulant film (11),
uncoiling the transparent protecting foil (12),
uncoiling a third layer of an adhesive encapsulant film (13),
lay-out of a multitude of glass tiles (14),
bringing out of terminal ribbons through the substrate (2) or through the transparent protecting foil (12),
vacuum laminating of the assembly,
trimming and finishing the strip (1)
